(19) United States
(12) Patent Application Publication
(10) Pub. No.: US 2025/0218514 A1
(43) Pub. Date: Jul. 3, 2025

(54) NEUROMORPHIC MEMORY DEVICE AND NEUROMORPHIC SYSTEM USING THE SAME

(71) Applicant: SEOUL NATIONAL UNIVERSITY R&DB FOUNDATION, Seoul (KR)

(72) Inventors: Woo Young CHOI, Seoul (KR); Bosung JEON, Seoul (KR)

(73) Assignee: SEOUL NATIONAL UNIVERSITY R&DB FOUNDATION, Seoul (KR)

(21) Appl. No.: 18/939,966

(22) Filed: Nov. 7, 2024

(30) Foreign Application Priority Data
Dec. 29, 2023 (KR) 10-2023-0196971
Sep. 24, 2024 (KR) 10-2024-0129264

(51) Int. Cl. G11C 16/04; G11C 16/24; G11C 16/26

(52) U.S. Cl. CPC G11C 16/0483; G11C 16/24; G11C 16/26

(57) ABSTRACT

The present disclosure relates to a neuromorphic memory device and a neuromorphic system using the same. The neuromorphic memory device includes a three-dimensional memory element including NAND cell strings, a bit line that outputs an output signal, forms a first axis of the three-dimensional memory element, and connects NAND cells existing on the same first axis among the NAND cell strings, a word line that receives an input signal, forms a second axis of the three-dimensional memory element, and connects NAND cells existing on the same second axis among the NAND cell strings, and a string selection line that forms a layer of an artificial intelligence neural network, forms a third axis of the three-dimensional memory element, and connects NAND cells existing on the same third axis among the NAND cell strings by intersecting the bit line and the word line.

### CROSS-REFERENCE TO RELATED PATENT APPLICATION

This application claims the benefit of Korean Patent Application No. 10-2024-01292644, filed on Sep. 24, 2024, and Korean Patent Application No. 10-2023-0196971, filed on Dec. 29, 2023, in the Korean Intellectual Property Office, the disclosure of which is incorporated herein in its entirety by reference.

### TECHNICAL FIELD

The present disclosure relates to neuromorphic technology, and more specifically, to efficient and reconfigurable NAND array neutral network layer mapping and an operation thereof for neuromorphic computation.

### BACKGROUND

Due to the technical and commercial success of deep learning, artificial intelligence is being used in various fields. However, since deep learning models largely consumes power, various neuromorphic-based technologies such as processing-in-Memory and compute-in-Memory are emerging. Among such technologies, a spiking neural network (SNN) using spike is known as an energy-efficient solution with very low power consumption.

The SNN includes a synapse array that store weight and a neuron that is responsible for activation. The SNN utilizes temporal coding of a network input and can implement low power due to low sparsity of spikes. The synapse array, one of the components of SNN, performs vector matrix multiplication (VMM) of a spike matrix, which is the network input, and learned weight, and exhibits a compute-in-memory function.

In the existing synapse array-related technology of SNN, memory cells (memristor elements such as RRAM and PRAM) using a cross-point type array and NOR/AND flash arrays are used, and the VMM is performed as the sum of currents in the bit line (bit line, BL) due to the spike matrix entering a word line (WL). However, in the case of NAND flash memory, since an internal string is composed of a serial connection of memory cells due to structural characteristics, it is not possible to receive input as a WL as in the existing method, but a method of receiving input as a string selection line (SSL) is used.

In the structure of a general neural network, the number of input signals is in the hundreds to thousands, and the existing technology as above requires simultaneous access to a large number of blocks, which places a great burden on the peripheral circuits including a word line driver (WL driver), and thus, high integration which is the greatest advantage of 3D NAND flash memory cannot effectively used.

Therefore, when a method that requires access to a minimum number of blocks and can best utilize the advantages of the integration of 3D NAND flash memory is found and applied to the SNN, it is expected that extremely economical hardware implementation of SNN will become possible.

### PRIOR ART DOCUMENT

### Patent Document

(Patent Document 1) Korean Patent Registration No. 10-2514650 (2023 Mar. 23)

### SUMMARY

One embodiment of the present disclosure is to provide a neuromorphic memory device capable of implementing an economic spiking neural network and a neuromorphic system using the neuromorphic memory device as a method that can most efficiently utilize NAND flash memory with a high cell integration.

One embodiment of the present disclosure is to provide a neuromorphic memory device and a neuromorphic system using the neuromorphic memory device, which can minimize the burden on peripheral circuits by requiring access to a minimum number of blocks through a mapping method that corresponds a neutral network layer to a string selection line (SSL) on a one-to-one basis.

According to an aspect of the present disclosure, there is provided a neuromorphic memory device including: a three-dimensional memory element including a plurality of NAND cell strings; a bit line that outputs an output signal, forms a first axis of the three-dimensional memory element, and connects NAND cells existing on the same first axis among the plurality of NAND cell strings; a word line that receives an input signal, forms a second axis of the three-dimensional memory element, and connects NAND cells existing on the same second axis among the plurality of NAND cell strings; and a string selection line that forms a layer of an artificial intelligence neural network, forms a third axis of the three-dimensional memory element, and connects NAND cells existing on the same third axis among the plurality of NAND cell strings by intersecting the bit line and the word line.

When the number of inputs of the artificial intelligence neural network is greater than the number of word lines, the neuromorphic memory device may configure the artificial intelligence neural network by configuring a network topology with the string selection lines.

The neuromorphic memory device may configure the network topology by bundling a plurality of adjacent string selection lines.

The neuromorphic memory device may configure the number of bit lines to be the same as the number of outputs of the artificial intelligence neural network.

The neuromorphic memory device may sequentially arrange the layers of the artificial intelligence neural network according to the increase in the string selection lines.

The neuromorphic memory device may implement a synapse of the artificial intelligence neural network through the NAND cells and stores weights in the NAND cells.

The neuromorphic memory device may perform a read operation of the artificial intelligence neural network only through a word line connected to the input signal when sparsity of the input signal is detected.

The neuromorphic memory device reads weight of the NAND cell by operating the bit line in a manner in which output currents are summed over time (temporal-sum).

According to another aspect of the present disclosure, there is provided a neuromorphic system using a neuromorphic memory, the neuromorphic system including: a neuromorphic memory device; and a neuromorphic computational device that processes input spikes and output spikes input and output through the neuromorphic memory device, in which the neuromorphic memory device includes a three-dimensional memory device that includes a NAND cell layer arranged along a first axis and a plurality of NAND cell strings each including a plurality of NAND cells arranged along a second axis within the NAND cell layer, and arranges the NAND cell layer along a third axis, a bit line that outputs the output spike, forms the first axis of the three-dimensional memory device, and connects NAND cells existing along the same first axis among the plurality of NAND cell strings, a word line that receives the input spike, forms the second axis of the three-dimensional memory device, and connects NAND cells existing along the same second axis among the plurality of NAND cell strings, and a string selection line that forms a layer of an artificial intelligence neural network, forms the third axis of the three-dimensional memory element, and connects NAND cells existing on the same third axis among the plurality of NAND cell strings by intersecting the bit line and the word line.

The neuromorphic memory device may configure the artificial intelligence neural network by configuring a network topology with the string selection line when the number of inputs of the artificial intelligence neural network is greater than the number of word lines.

The neuromorphic memory device may configure the number of bit lines so that the number of outputs of the artificial intelligence neural network is the same.

The neuromorphic memory device may sequentially arrange layers of the artificial intelligence neural network according to an increase in the string selection line.

The neuromorphic memory device may implement synapses of the artificial intelligence neural network through the NAND cells and store weights in the NAND cells.

The neuromorphic memory device may perform a read operation of the artificial intelligence neural network only through a word line connected to the input spike when sparsity of the input spike is detected.

The neuromorphic memory device reads weight of the NAND cell by operating the bit line in a manner in which output currents are summed over time (temporal-sum).

The disclosed technology may have the following effects. However, it does not mean that a specific embodiment must include all or only the following effects, and therefore, the scope of the disclosed technology should not be understood as being limited thereby.

According to the neuromorphic memory device and the neuromorphic system using the same according to one embodiment of the present disclosure, it is possible to obtain effects of increasing memory utilization within a single block by being able to use all word line layers.

In addition, according to the neuromorphic memory device and the neuromorphic system using the same according to one embodiment of the present disclosure, it is possible to obtain effects of being usable in various network topologies by being reconfigurable according to the network size.

In addition, according to the neuromorphic memory device and the neuromorphic system using the same according to one embodiment of the present disclosure, it is possible to obtain effects of being able to operate at low power by performing the read operation only on a word line where the input spike occurs through control logic.

### BRIEF DESCRIPTION OF THE DRAWINGS

FIG. 1 is a diagram for explaining the neuromorphic memory device according to the present disclosure.

FIG. 2 and FIG. 3 are diagrams for explaining weight mapping of the neuromorphic memory device according to one embodiment of the present disclosure.

FIG. 4 is a diagram for explaining a layer to SSL mapping (LSM) method of a 3D NAND-based neuromorphic memory device according to one embodiment of the present disclosure.

FIG. 5 is a diagram for explaining a network reconfiguration of the neuromorphic memory device according to one embodiment of the present disclosure.

FIG. 6 is a diagram for explaining a neural network inference operation of a neuromorphic system using a neuromorphic memory according to the present disclosure.

FIG. 7 is a graph showing cell utilization within a block of a proposed LSM method of the present disclosure compared to the existing method.

FIG. 8 is a graph showing simulation results for an SNN inference operation.

[National research and development project supporting the present invention] [Project Serial No] 2710006193
[Tax Project No] RS-2024-00402495
[Name of department] Ministry of Science and ICT
[Task management (professional) institution name] National Research Foundation of Korea
[Research Project name] Development of next-generation intelligent semiconductor technology (devices)
[Research Task Name] Synapse devices and new device-based neuron circuits for improving SNN performance
[Name of task performing organization] Seoul National University
[Research period] Jan. 1, 2023 to Dec. 31, 2023
[National research and development project supporting the present invention] [Project Serial No] 1711186719
[Tax Project No] 2022M317A1078544
[Name of department] Ministry of Science and ICT
[Task management (professional) institution name] National Research Foundation of Korea
[Research Project name] Development of PIM artificial intelligence semiconductor core technology (devices)
[Research Task Name] Development of silicon-based PIM specialized devices, circuits, and application technologies
[Name of task performing organization] Seoul National University
[Research period] Jan. 1, 2023 to Dec. 31, 2023

### DETAILED DESCRIPTION

Specific structural or functional descriptions in the embodiments of the present disclosure are only for description of the embodiments of the present disclosure. The descriptions should not be construed as being limited to the embodiments described in the specification or application. That is, the present disclosure may be embodied in many different forms, but should be construed as covering modifications, equivalents or alternatives falling within ideas and technical scopes of the present disclosure. Since the objects or effects set forth in the present disclosure do not mean that a specific embodiment must include all of them or only such effects, the scope of the present disclosure should not be understood as being limited thereto.

Meanwhile, the meanings of the terms described in this application should be understood as follows.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be understood that when an element is referred to as being “coupled” or “connected” to another element, it can be directly coupled or connected to the other element or intervening elements may be present therebetween. In contrast, it should be understood that when an element is referred to as being “directly coupled” or “directly connected” to another element, there are no intervening elements present. Other expressions that explain the relationship between elements, such as “between”, “directly between”, “adjacent to” or directly adjacent to” should be construed in the same way.

In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

The identification codes (e.g., a, b, c, etc.) in each step are used for convenience of explanation and do not describe the order of each step. The steps may occur in a different order, unless the context clearly dictates otherwise. That is, the steps may be performed in a specified order, may be performed substantially simultaneously, or may be performed in reverse order.

Unless otherwise defined, all terms including technical and scientific terms used herein have the same meaning as commonly understood by one of ordinary skill in the art to which the present disclosure belongs. It will be further understood that terms used herein should be interpreted as having a meaning that is consistent with their meaning in the context of this specification and the relevant art and will not be interpreted in an idealized or overly formal sense unless expressly so defined herein.

Hereinafter, with reference to the attached drawings, a preferred embodiment of the present disclosure will be described in more detail. Hereinafter, the same reference numerals are used for the same components in the drawings, and duplicate descriptions for the same components are omitted.

In the case of a general NAND flash memory, due to a serial connection structure of cells in a string, a string select transistor (SSL, DSL) or a bit line BL is used as an input instead of a word lines WL for a neuromorphic application, but this has a disadvantage in that cells in a block cannot be used efficiently. Therefore, the present disclosure proposes a neuromorphic memory device that enables the use of NAND flash memory as a high-density, energy-efficient neuromorphic synapse element by solving this problem.

More specifically, the present disclosure proposes the most efficient weight transfer method for neuromorphic computation in 2D and 3D NAND flash memories, a method that can be reconfigured for various neural network topologies, and an energy-efficient operation method for operating them.

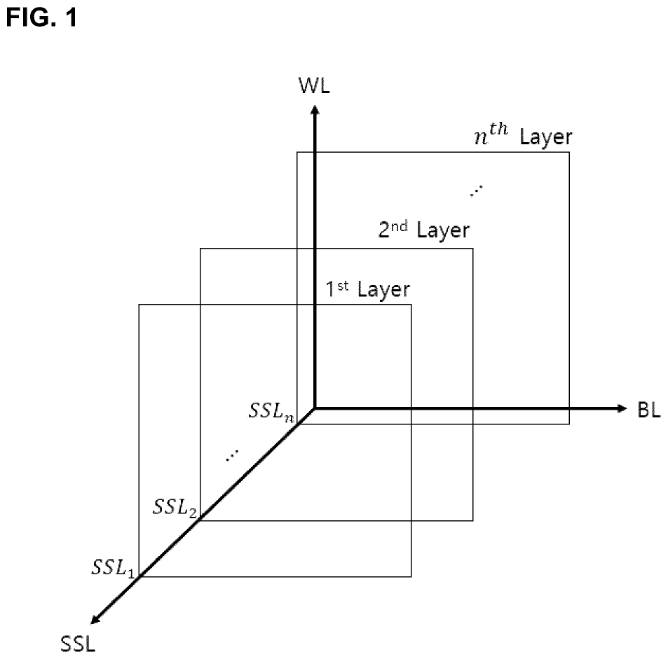

FIG. 1 is a diagram for explaining a neuromorphic memory device according to the present disclosure.

Referring to FIG. 1, a neuromorphic memory device may be implemented by including a three-dimensional memory element composed of a plurality of NAND cell strings. The NAND cell string is a structure in which a plurality of NAND cells are connected in series, and when this string is stacked in a multi-layer structure, a 3D structure may be formed.

In addition, the neuromorphic memory device may be implemented by including a bit line BL that constitutes a first axis of a three-dimensional memory element, a word line WL that constitutes the second axis, and a string selection line SSL that constitutes the third axis.

The bit line BL may output an output signal, constitute the first axis of a three-dimensional memory element, and connect NAND cells existing on the same first axis among the plurality of NAND cell strings.

The word line WL may receive an input signal, constitute the second axis of a three-dimensional memory element, and connect NAND cells existing on the same second axis among the plurality of NAND cell strings.

The string selection line SSL may constitute a layer of an artificial intelligence neural network, constitute the third axis of a three-dimensional memory element, and connect NAND cells existing on the same third axis among the plurality of NAND cell strings by intersecting with the bit line BL and the word line WL.

The neuromorphic memory device may sequentially arrange the layers (1st Layer, 2nd Layer, . . . , nth Layer) of the artificial intelligence neural network according to increase of the string selection lines (SSL₁, SSL₂, . . . , and SSLₙ), and may implement a synapse of the artificial intelligence neural network through the NAND cells and store weights in the NAND cells.

In this way, when the layers of the artificial intelligence neural network are corresponded to the string selection line (SSL), effects of improving area and energy efficiency can be obtained by using fewer 3D NAND blocks.

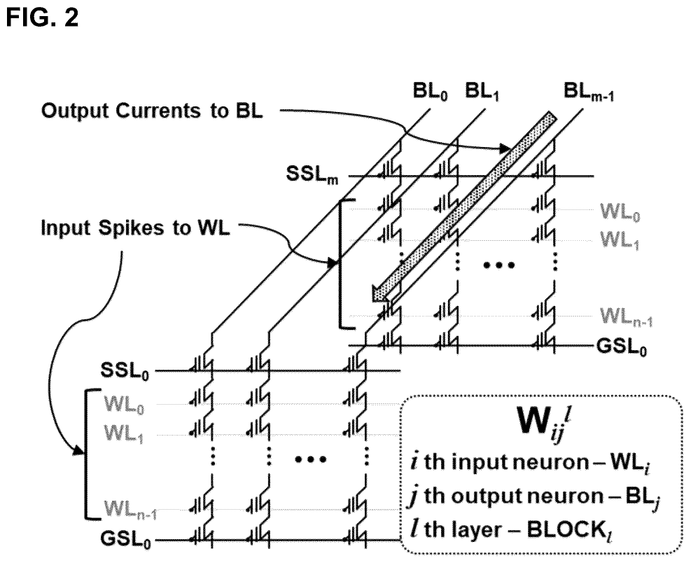

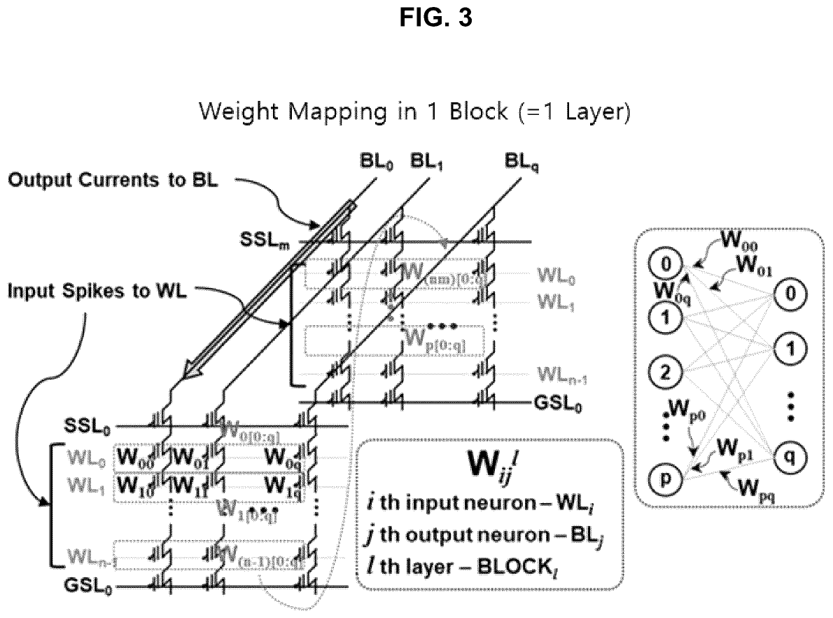

FIG. 2 and FIG. 3 are diagrams for explaining weight mapping of the neuromorphic memory device according to one embodiment of the present disclosure.

First, FIG. 2 shows a layer to SSL mapping (LSM) method that corresponds a neutral network layer to the string selection line SSL a one-to-one basis. Specifically, weight Wᵢⱼ^{t} of a 1th layer connecting an ith input neuron and a jth output neuron may be corresponded to a cell where an ith word line WLᵢ and a jth bit line BLⱼ intersect. At this time, the weight of other layers of the artificial intelligence neural network may be assigned to other blocks or other word line planes.

Next, FIG. 3 is a drawing specifically showing the weight mapping method within a block. Since all word line WL layers may be used, the number of required string selection lines SSLs is the same as the number of network layers, so that as many weights as possible can be corresponded within one block. Therefore, the LSM method proposed in the present disclosure provides maximum efficiency in cell arrangement within a block, and can obtain the effect of increased area efficiency by using a minimum number of blocks during network transfer.

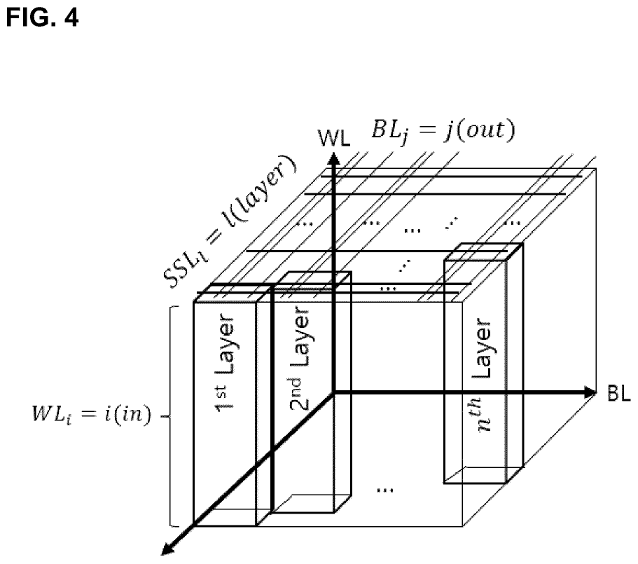

FIG. 4 is a diagram for explaining the layer to SSL mapping (LSM) method of a 3D NAND-based neuromorphic memory device according to one embodiment of the present disclosure.

In the related art, a layer-to-WL mapping (LWM) method, which corresponds one layer of the network to one word line WL, is used. While a typical commercial NAND memory structure has hundreds of word lines WLs, the structure of a neural network has a depth of less than several dozen layers. Therefore, the remaining word lines WLs are not utilized, and the number of cells that can actually be used in one block becomes very small.

After that, a layer-to-BL mapping (LBM) method, which corresponds one layer of the network to one bit line BL, is used. However, this method accepts the input of the network as a string selection line SSL, and considering that a typical NAND memory structure has only 4 to 12 string selection lines SSLs in one block, a typical neural network that requires hundreds of inputs requires simultaneous access to several dozen blocks. Although it has the advantage of being able to utilize all word lines WLs, the available cells in one block are still limited.

Therefore, the present disclosure proposed a layer to SSL mapping (LSM) method that maps one layer of the network to the string selection line SSL, as shown in FIG. 4. The LSM method proposed in the present disclosure may utilize all word line WL, and the number of required string selection lines SSLs is the same as the depth (number of layers) of the network, so that as many weights as possible can correspond in one block.

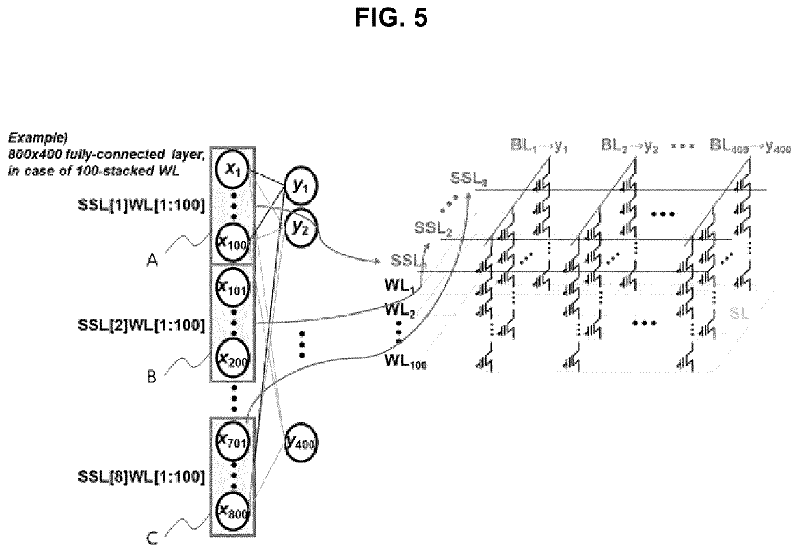

FIG. 5 is a diagram explaining a network reconfiguration of the neuromorphic memory device according to one embodiment of the present disclosure.

Referring to FIG. 5, the neuromorphic memory device may configure the artificial intelligence neural network by configuring a network topology with the string selection lines SSLs when the number of inputs (p) of the artificial intelligence neural network is greater than the number of word lines WLs (n) (p>n). The neuromorphic memory device may form the network topology by grouping the plurality of adjacent string selection lines SSLs. For example, in the case of an 800×400 fully-connected layer and a word line WL layer of 100, mapping is possible by dividing (A, B, C) into different string selection lines SSLs within the same block, as shown in FIG. 5. In a network with a large number of inputs, inputs may be mapped to a combination of string selection lines SSLs and word lines WLs, which minimizes the increase in the number of blocks.

In addition, even when the number of outputs of the artificial intelligence neural network is sufficiently large, since the bit line BL exists as large as the size of the page buffer (4k to 16k), the bit lines can all be allocated within one block. In a network with a large number of outputs, the number of bit lines BLs utilized can be increased, that is, bit lines can be configured to be the same as the number of outputs.

Meanwhile, the network depth (the number of layers) may be mapped to a separate word line plane or block.

Therefore, one embodiment of the present disclosure can be reconfigured according to the size of the network, so the present disclosure can be applied to various network topologies. In addition, there is a dispersion according to the word line WL location due to process problems and write and read operation problems in a NAND flash memory, but when weights are mapped as in the present disclosure, the dispersions occurring in these problems can be averaged-out.

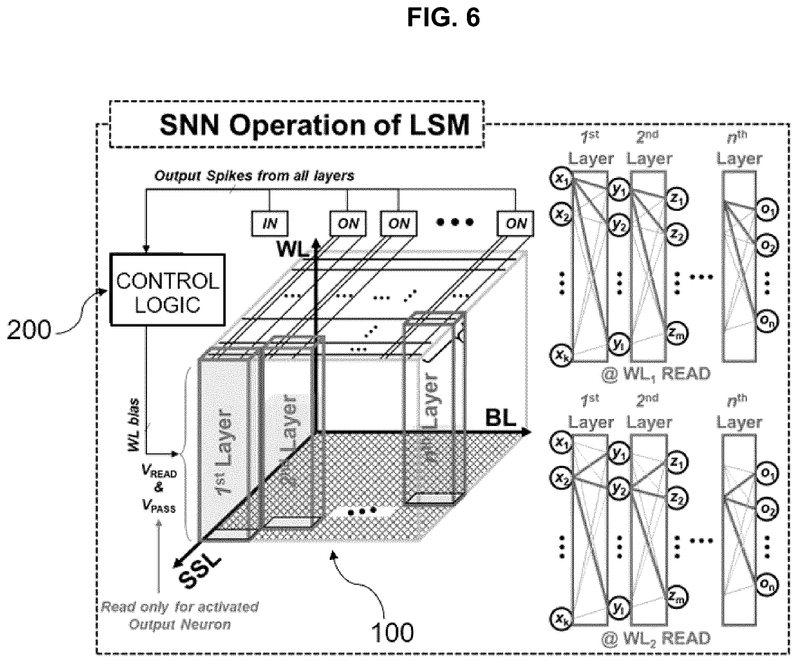

FIG. 6 is a diagram for explaining a neural network inference operation of a neuromorphic system using a neuromorphic memory according to the present disclosure.

Referring to FIG. 6, the neuromorphic system may include a neuromorphic memory device 100 and a neuromorphic computational device 200. Here, the neuromorphic computational device 200 may process an input spike and an output spike input and output through the neuromorphic memory device 100.

The neuromorphic memory device 100 may use the three-dimensional memory element as a synapse based on a layer-to-SSL mapping (LSM) that corresponds the layer of the artificial intelligence neural network to a string selection line SSL a one-to-one basis. To this end, the neuromorphic memory device 100 is configured to include the three-dimensional memory element, the bit line BL, the word line WL, and the string selection line SSL.

The three-dimensional memory element may correspond to a 3D NAND. That is, the three-dimensional memory element includes a NAND cell layer arranged as the first axis, a plurality of NAND cell strings each including a plurality of NAND cells arranged as the second axis within the NAND cell layer, and arranges the NAND cell layer as the third axis.

The bit line BL outputs an output spike and configures the first axis of the three-dimensional memory element. The bit line BL connects the NAND cells existing in the same first axis among the plurality of NAND cell strings.

The word line WL receives the input spike and forms the second axis of the three-dimensional memory element. The word line WL connects NAND cells existing on the same second axis among the plurality of multiple NAND cell strings.

The string selection line SSL forms the layer of the artificial intelligence neural network and forms the third axis of the three-dimensional memory element. The string selection line SSL intersects with the bit line BL and the word line WL to connect NAND cells existing on the same third axis among the plurality of NAND cell strings. Here, the artificial intelligence neural network may correspond to a spiking neural network (SNN) that uses spikes.

The neuromorphic computational device 200 may perform a read operation only on the word line WL where the input spike occurs through control logic by utilizing the sparsity input, which is one of the characteristics of the SNN.

In the case of SNN inference using the existing NAND flash memory, in order to operate without distortion, each word line WL should be read sequentially, and since sequential reading is performed as many times as the number of layers of the neural network, a delay in the operation occurs, and since all word lines WLs of a plurality of blocks should be controlled, a large amount of energy is consumed in the peripheral circuit. In addition, in the case of a method that sequentially turns on all word lines WLs only when an input spike comes in, all word lines WLs must be turned on because all word lines should be transmitted to all output neurons. This method also causes unnecessary word lines WLs to be turned on, and since multiple block accesses are required, a large amount of energy is consumed in the peripheral circuit.

However, as shown in FIG. 6, in the present disclosure, only the minimum number of blocks needs to be controlled, so the energy required in the peripheral circuit is relatively small, and since only the word lines WLs where the input comes in need to be read, unnecessary control of word lines WLs is not required. Therefore, pure event-driven operation is possible, and effects of very low-power operation of both the cell and the surrounding circuit can be obtained.

In addition, since the present disclosure recognizes sparsity and applies an operation method that utilizes the sparsity, it can be expanded and applied to all SNN technologies that utilize sparsity in the future, and since the present disclosure does not uses a method (spatio-sum) in which all currents are combined spatially in one bit line BL but uses a method (temporal-sum) in which all currents are combined over time, only one cell can be read from the bit line BL at the same time. Therefore, the line resistance problems that occurs in the SNN inference operation can be greatly alleviated.

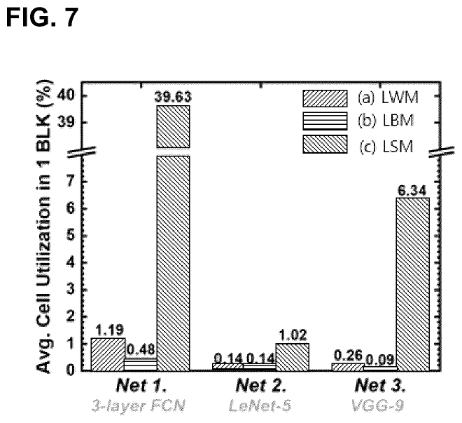

FIG. 7 is a graph showing cell utilization within a block of a proposed LSM method of the present disclosure compared to the existing method.

Referring to FIG. 7, (a) and (b) on the graph are the existing LWM and LBM methods, and (c) is the LSM method proposed in the present disclosure, and (c) shows the intra-block cell utilization in various networks. Here, three neural networks were used. Net 1 is a 784×800×400×10 FCN (fully-connected network), and Net 2 and Net 3 are LeNet-5 and VGG-9, respectively. It can be seen that the LSM method proposed in the present disclosure shows higher intra-block cell utilization in various networks because the required number of blocks is minimized compared to the existing LWM and LBM methods. For example, in Net 1, the LSM method showed 33.3 times higher cell utilization than the existing LWM method, in Net 2, the LSM method showed 7.3 times higher cell utilization than the existing LWM and LBM methods, and in Net 3, the LSM method showed 24.4 times higher cell utilization than the existing LWM method. In a fully-connected network (FCL) and convolution layer (CL) which are the basic components of neural networks, the efficiency was maximized when mapping the FCL having a large number of parameters, and the CL also increased in mapping efficiency as the network size increased. The LSM method proposed in the present disclosure can be seen to be able to take advantage of the high-integration 3D NAND by completing mapping with a smaller number of blocks than the existing method without changing the commercial 3D NAND structure.

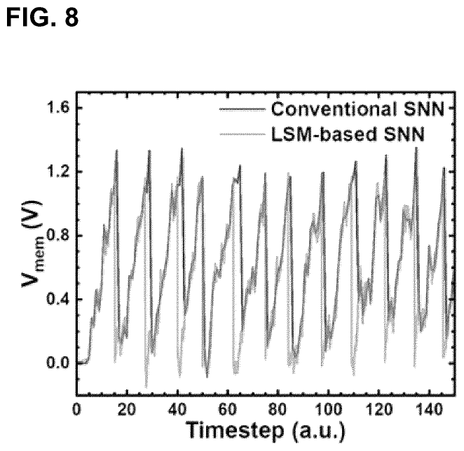

FIG. 8 is a graph showing the simulation results for the SNN inference operation.

Referring to FIG. 8, the membrane voltage of a specific neuron over time was confirmed, and it can be seen that the LSM-based SNN operation of the present disclosure is the same as the result of the existing SNN operation method after the spike operation of the network converges. Accordingly, it can be confirmed that the operation possibility compatible with the SNN inference method is shown, and that the NAND flash memory can be applied to the SNN by applying the present disclosure.

Although the present disclosure has been described above with reference to preferred embodiments thereof, it will be understood by those skilled in the art that the present disclosure may be variously modified and altered without departing from the spirit and scope of the present disclosure set forth in the claims below.

[Detailed Description of Main Elements]

100: neuromorphic memory device
200: neuromorphic computational device
WL: word line
BL: bit line
SSL: string selection line

What is claimed is:

1. A neuromorphic memory device comprising:
a three-dimensional memory element including a plurality of NAND cell strings;
a bit line that outputs an output signal, forms a first axis of the three-dimensional memory element, and connects NAND cells existing on the same first axis among the plurality of NAND cell strings;
a word line that receives an input signal, forms a second axis of the three-dimensional memory element, and connects NAND cells existing on the same second axis among the plurality of NAND cell strings; and
a string selection line that forms a layer of an artificial intelligence neural network, forms a third axis of the three-dimensional memory element, and connects NAND cells existing on the same third axis among the plurality of NAND cell strings by intersecting the bit line and the word line.

2. The neuromorphic memory device of claim 1, wherein when the number of inputs of the artificial intelligence neural network is greater than the number of word lines, the neuromorphic memory device configures the artificial intelligence neural network by configuring a network topology with the string selection lines.

3. The neuromorphic memory device of claim 2, wherein the neuromorphic memory device configures the network topology by bundling a plurality of adjacent string selection lines.

4. The neuromorphic memory device of claim 1, wherein the neuromorphic memory device configures the number of bit lines to be the same as the number of outputs of the artificial intelligence neural network.

5. The neuromorphic memory device of claim 1, wherein the neuromorphic memory device sequentially arranges the layers of the artificial intelligence neural network according to the increase in the string selection lines.

6. The neuromorphic memory device of claim 1, wherein the neuromorphic memory device implements a synapse of the artificial intelligence neural network through the NAND cells and stores weights in the NAND cells.

7. The neuromorphic memory device of claim 1, wherein the neuromorphic memory device performs a read operation of the artificial intelligence neural network only through a word line connected to the input signal when sparsity of the input signal is detected.

8. The neuromorphic memory device of claim 1, wherein the neuromorphic memory device reads weight of the NAND cell by operating the bit line in a manner in which output currents are summed over time (temporal-sum).

9. A neuromorphic system comprising:
a neuromorphic memory device; and
a neuromorphic computational device that processes input spikes and output spikes input and output through the neuromorphic memory device,
wherein the neuromorphic memory device uses a neuromorphic memory including
a three-dimensional memory device that includes a NAND cell layer arranged along a first axis and a plurality of NAND cell strings each including a plurality of NAND cells arranged along a second axis within the NAND cell layer, and arranges the NAND cell layer along a third axis,
a bit line that outputs the output spike, forms the first axis of the three-dimensional memory device, and connects NAND cells existing along the same first axis among the plurality of NAND cell strings,
a word line that receives the input spike, forms the second axis of the three-dimensional memory device, and connects NAND cells existing along the same second axis among the plurality of NAND cell strings, and
a string selection line that forms a layer of an artificial intelligence neural network, forms the third axis of the three-dimensional memory element, and connects NAND cells existing on the same third axis among the plurality of NAND cell strings by intersecting the bit line and the word line.

10. The neuromorphic system of claim 9, wherein the artificial intelligence neural network is a spiking neural network (SNN).

11. The neuromorphic system of claim 9, wherein the neuromorphic memory device configures the artificial intelligence neural network by configuring a network topology with the string selection line when the number of inputs of the artificial intelligence neural network is greater than the number of word lines.

12. The neuromorphic system of claim 9, wherein the neuromorphic memory device configures the number of bit lines so that the number of outputs of the artificial intelligence neural network is the same.

13. The neuromorphic system of claim 9, wherein the neuromorphic memory device sequentially arranges layers of the artificial intelligence neural network according to an increase in the string selection line.

14. The neuromorphic system of claim 9, wherein the neuromorphic memory device implements synapses of the artificial intelligence neural network through the NAND cells and stores weights in the NAND cells.

15. The neuromorphic system of claim 9, wherein the neuromorphic memory device performs a read operation of the artificial intelligence neural network only through a word line connected to the input spike when sparsity of the input spike is detected.

16. The neuromorphic system of claim 9, wherein the neuromorphic memory device reads weight of the NAND cell by operating the bit line in a manner in which output currents are summed over time (temporal-sum).
